(19) United States
(12) Patent Application Publication
(10) Pub. No.: US 2006/0215369 A1
(43) Pub. Date: Sep. 28, 2006

(54) Heat radiating device and electronic equipment mounted on vehicle

(75) Inventors: Yasushi Ohashi, Kariya-city (JP); Takushi Maeda, Kariya-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/388,063

(22) Filed: Mar. 23, 2006

(30) Foreign Application Priority Data
Mar. 23, 2005 (JP) 2005-084059

(51) Int. Cl. H05K 7/20

(52) U.S. Cl. 361/704

(57) ABSTRACT

In a heat radiating device and electronic equipment mounted on a vehicle, grid-shaped grooves 16 are formed on a lower face of a fan casing 7 which functions as a heat sink, and an annular ditch 15 is formed a round a region in which the grid-shaped grooves 16 are formed. Heat-conductive grease 14 interposed between IC chip 5 and a lower face of the fan casing 7 is prevented by the grid-shaped grooves 16 from slipping out. Even when a quantity of the coated heat-conductive grease 14 is excessively large in the beginning and forced out from a region in which the grid-shaped grooves 16 are formed, the heat-conductive grease 14, which has forced out in this way, is stored in an annular ditch 15 and not forced outside. In a cooling device in which heat of an object to be cooled is transmitted to a heat sink via the heat-conductive grease and radiated outside, the heat-conductive grease is prevented from being forced out from between the object to be cooled and the heat sink.

### BACKGROUND OF THE INVENTION

1. Field of the Invention

The present invention relates to a cooling device in which the heat of an object, such as an electronic or electric part, to be cooled is transmitted to a heat sink via a heat-conductive grease and radiated outside. The present invention also relates to electronic equipment mounted on a vehicle in which the heat radiating device is provided.

2. Description of the Related Art

In the electronic equipment mounted on a vehicle, such as a car navigation device, a capacity for data has been greatly increased and, further, an IC chip to be used for the electronic equipment has been downsized and the performance has been enhanced. For the above reasons, there is a tendency that a quantity of heat generated per unit area of the IC chip has increased. Therefore, various devices have been developed to cool the electronic equipment.

Basically, a cooling device for cooling the IC chip is composed in such a manner that the heat generated by the IC chip is transmitted to a heat sink and then radiated outside from the heat sink. For example, a cooling device described in the official gazette of JP-A-2000-105635 is used for a lap-top-type personal computer, in which the heat generated by CPU is radiated from a keyboard via a heat-conductive body or radiated from a housing via the heat-conductive body. Alternatively, a CPU and a cooling fan are arranged in series and both are combined with each other by a heat-conductive body and this heat-conductive body is cooled by the cooling fan.

In order to enhance the heat conductivity between an IC chip and a heat sink, a heat-conductive grease is interposed between the IC chip and the heat sink in a heat radiating device. In this heat radiating device in which heat-conductive grease is used, the following problems may be encountered. In the case where an excessively large quantity of heat-conductive grease is coated or in the case where an external force such as vibration caused by a vehicle is given to the electronic equipment mounted on the vehicle, the heat-conductive grease is forced out from between the IC chip and the heat sink. There is a possibility that the thus forced-out heat-conductive grease is further given an external force and attaches to other electronic parts or connectors or contact points of switches.

### SUMMARY OF THE INVENTION

The present invention has been accomplished in view of the above circumstances. An object of the present invention is to provide a heat radiating device capable of preventing heat-conductive grease from being forced out from between an object to be cooled and a heat sink. Another object of the present invention is to provide electronic equipment, mounted on a vehicle, in which the heat radiating device is provided.

The present invention provides a heat radiating device in which a heat sink is contacted with an object to be cooled such as an electronic or electric part via heat-conductive grease and the heat of the object to be cooled is transmitted to the heat sink and radiated outside from the heat sink, wherein the heat sink includes a recess portion formed round a portion of the heat sink with which the heat-conductive grease is contacted.

According to this constitution, heat-conductive grease, which is going to be forced out from between the object to be cooled and the heat sink, is accommodated in the recess portion. Therefore, no heat-conductive grease is forced outside.

In this case, the recess portion may be intermittently (discontinuously) formed round a portion of the heat sink with which the heat-conductive grease is contacted. However, it is preferable that the recess portion is formed into a closed-loop-shape (is continuous). When the recess portion is formed into a closed-loop-shape, it is possible to more positively prevent the heat-conductive grease from being forced out.

It is preferable that an outer edge of the recess portion is located inside of an outer edge of the object to be cooled. When the outer edge of the recess portion is located inside of the outer edge of the object to be cooled, a gap formed between the outer portion of the recess portion and the object to be cooled can be very small. Therefore, it is possible to more positively prevent the heat-conductive grease from being forced out from between the object to be cooled and the heat sink.

The above heat radiating device can be provided in electronic equipment mounted on a vehicle. Electronic equipment mounted on a vehicle is subjected to vibration when a vehicle, on which the electronic equipment is mounted, is running. Further, the electronic equipment mounted on a vehicle is exposed to a severe thermal environment in summer in which a temperature in the vehicle is raised abnormally high. Even in this electronic equipment mounted on the vehicle, it is possible to effectively prevent the heat-conductive grease from being forced out.

The present invention may be more fully understood from the description of preferred embodiments of the invention, as set forth below, together with the accompanying drawings.

### BRIEF DESCRIPTION OF THE DRAWINGS

In the drawings:

FIG. 1 is a sectional side view showing a primary portion of the first embodiment of the present invention;

FIG. 2 is a perspective view showing a primary portion of a lower face of a fan casing;

FIG. 3 is a sectional view of a housing;

FIG. 4 is a sectional side view showing a primary portion of the second embodiment of the present invention; and

FIG. 5 is a sectional side view showing a primary portion of the third embodiment of the present invention.

### DESCRIPTION OF THE PREFERRED EMBODIMENTS

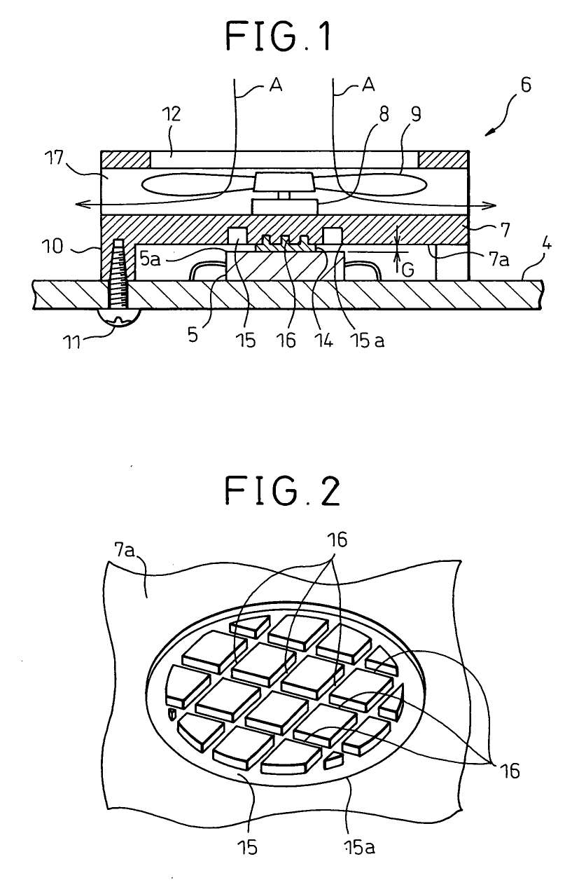

Referring to FIGS. 1 to 3, explanations will be made into the first embodiment of the present invention applied to a car navigation device which is electronic equipment mounted on a vehicle.

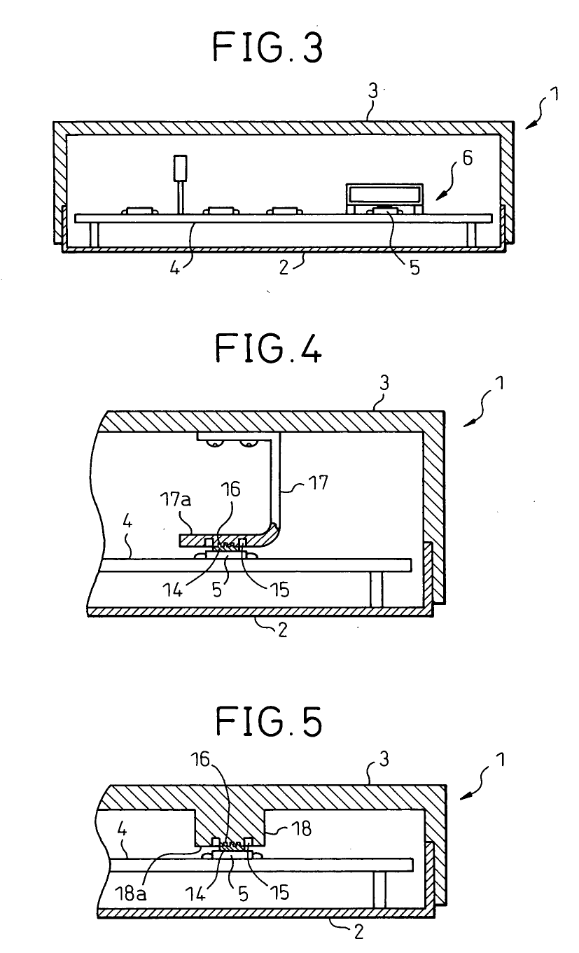

FIG. 3 is a view showing a housing 1 for accommodating a control unit of the car navigation device. This housing 1 includes a metallic main body 2 composed of an iron plate and a metallic lid body 3, for example, made of aluminum, wherein this metallic lid body 3 covers the main body 2. Although not shown in the drawing, slits for ventilation are provided in the main body 2 and the lid body 3.

In this housing 1, a printed wiring board 4 is provided. On this printed wiring board 4, various electric and electronic parts composing the control unit are mounted. In FIG. 1, IC chip 5 composes, for example, CPU which is one of the electric and electronic parts. This IC chip 5 corresponds to an object to be cooled. Above this IC chip 5, a cooling fan device 6 is arranged.

In this cooling fan device 6, a fan 9, which is rotated by a small motor 8, is arranged in a fan casing 7 made by means of aluminum die casting. At four corners of the fan casing 7, attaching legs 10 are protrude. These attaching legs 10 are fastened and fixed onto the printed wiring board 4 by screws 11. When the fan 9 is rotated by the small motor 8 in this cooling fan device 6, as shown by arrow A in FIG. 1, air is sucked from a suction hole 12 formed on an upper face of the fan casing 7 and discharged from a discharge hole 13 formed on a side of the fan casing 7.

In this embodiment, heat generated by IC chip 5 is first transmitted to the fan casing 7 of the cooling fan device 6. The heat transmitted to the fan casing 7 in this way is radiated into a current of air generated by the fan 9, so that the fan casing 7 can be cooled. In this way, the heat generated by IC chip 5 is transmitted to the fan casing 7, which functions as a heat sink, and radiated outside from the fan casing 7.

In this case, in order to facilitate the heat conduction from IC chip to the fan casing 7, heat-conductive grease 14 is interposed between IC chip 5 and the lower face 7a of the fan casing 7. This heat-conductive grease 14 is previously coated on one of IC chip 5 and the lower face 7a of the fan casing 7 and, for example, coated on the lower face 7a of the fan casing 7. When the fan casing 7 is fixed onto the printed wiring board 4 by screws 11, the heat-conductive grease 14 comes into contact with an upper face of IC chip 5 and is pressed between the upper face of IC chip 5 and the lower face 7a of the fan casing 7. Therefore, while the heat-conductive grease 14 is spreading in a gap formed between them, it is closely contacted with them.

As shown in FIG. 2, on the lower face 7a of the fan casing 7, a closed-loop-shaped annular ditch 15 is formed round a circular region with which the heat-conductive grease 14 is contacted. Further, in the circular region surrounded by the annular ditch 15, grooves 16 are formed into a grid-shape. In this case, an outer edge 15a of the annular ditch 15 is located inside an outer edge 5a of IC chip 5.

In the case where a quantity of the heat-conductive grease 14 coated on the fan casing 7 is excessively large, at the time of fixing the fan casing 7 onto the printed wiring board 4, the heat-conductive grease 14 is pressed between IC chip 5 and the lower face 7a of the fan casing 7 and spread outside the region in which the grid-shaped grooves are formed in some cases. However, in this embodiment, on the lower face 7a of the fan casing 7, the annular ditch 15 is formed in such a manner that the annular ditch 15 surrounds a region with which the heat-conductive grease 14 is contacted. Accordingly, the heat-conductive grease 14, which has spread outside the region in which the grid-shaped grooves 16 are formed, enters the inside the annular ditch 15 and is stored in it. Therefore, it is possible to prevent the heat-conductive grease 14 from being forced outside from IC chip 5. Accordingly, the heat-conductive grease 14 can be effectively prevented from attaching to connectors or contact points of switches arranged on the printed wiring board 4 or in the housing 1.

In this case, if the outer edge 15a of the annular ditch 15 is located inside the outer edge 5a of IC chip 5, gap G formed between the outer circumferential portion of the annular ditch 15 and IC chip 5 is very small (for example, about 0.4 mm). Therefore, the heat-conductive grease 14 can be positively prevented from slipping out from the inside of the annular ditch 15 to the outer circumferential side.

As the grid-shaped grooves 16 are provided in a region on the lower face 7a of the fan casing 7 with which the heat-conductive grease 14 is contacted, when the heat-conductive grease 14 is pressed between IC chip 5 and the lower face 7a of the fan casing 7, the heat-conductive grease 14 tightly enters the grid-shaped grooves 16. When the heat-conductive grease 14 intrudes (bites) into the grid-shaped grooves 16 as described above, slippage of the heat-conductive grease 14 can be prevented.

The housing 1 is arranged in a vehicle body in such a manner that the housing 1 is horizontally laid so that the lid body 3 can be located at an upper position and the main body 2 can be located at a lower position. Alternatively, the housing 1 is arranged in a vehicle body in such a manner that the housing 1 is vertical so that the main body 2 and the lid body 3 are respectively located in the lateral direction. When the vehicle is moved, the housing 1 vibrates. Due to this vibration or a thermal influence, the heat-conductive grease 14 is moved in some cases although the heat-conductive grease 14 is held by the grid-shaped grooves 16. Even when the heat-conductive grease 14 slips out of the grid-shaped grooves 16, as the annular ditch 15 is formed round the region in which the grid-shaped grooves 16 are formed, the heat-conductive grease 14 enters the annular ditch 15 and is prevented from being forced out onto the outer circumferential side of the annular ditch 15.

FIG. 4 is a view showing the second embodiment of the present invention. In this embodiment, a substantially C-shaped heat-conductive plate 17, which functions as a heat sink, is attached to the lid body 3. When the lid body 3 is attached to the main body 2, a lower piece 17a of the heat-conductive plate 17 comes into contact with IC chip 5 via the heat-conductive grease 14. In this case, in the same manner as that of the first embodiment described before, the annular ditch 15 and the grid-shaped grooves 16 are formed on the lower side 7a of the heat-conductive plate 17.

FIG. 5 is a view showing the third embodiment of the present invention. In this embodiment, a protruding portion 18, which functions as a heat sink, is integrally formed in the lid body 3. Therefore, when the lid body 3 is attached to the main body 2, a lower face 18a of the protruding portion 18 comes into contact with IC chip 5 via the heat-conductive grease 14. In this case, the annular ditch 15 and the grid-shaped grooves 16 are formed on a lower face 18a of the protruding portion 18 in the same manner as that of the first embodiment described before.

In this connection, it should be noted that the present invention is not limited to the above specific embodiment. Extensions and variations can be made as follows.

It is necessary that the inner edge of the annular ditch 15 is located inside the outer edge 5a of IC chip 5. However, the outer edge 15a of the annular ditch 15 may coincide with the outer edge 5a of IC chip 5. Alternatively, the outer edge 15a of the annular ditch 15 may be located outside the outer edge 15a of IC chip 5.

The recess portion, which is formed and surrounds the portion with which the heat-conductive grease 14 is contacted, is not necessarily formed into a closed-loop-shape like the annular ditch 15 of the above embodiment. It is sufficient that the recess portion is formed into a shape in which a plurality of grooves are continuously located at intervals and surround the portion with which the heat-conductive grease 14 is contacted. In this case, discontinuous portions of the plurality of grooves may be arranged on an upper side.

A shape of the grooves 16 for preventing a slippage of the heat-conductive grease 14 is not necessarily limited to a grid-shape. The shape of the grooves 16 may be circular or rectangular.

The grooves 16 may not be necessarily provided.

The object to be cooled is not necessarily limited to IC chip.

While the invention has been described by reference to specific embodiments chosen for purposes of illustration, it should be apparent that numerous modifications could be made thereto by those skilled in the art without departing from the basic concept and scope of the invention.

What is claimed is:

1. A heat radiating device in which a heat sink is contacted with an object to be cooled, such as an electronic or electric part, via heat-conductive grease and the heat of the object to be cooled is transmitted to the heat sink and radiated outside from the heat sink, wherein the heat sink includes a recess portion formed around a portion of the heat sink with which the heat-conductive grease is contacted.

2. A heat radiating device according to claim 1, wherein the recess portion is formed into a closed-loop-shape.

3. A heat radiating device according to claim 1, wherein the recess portion is located inside of an outer edge of an object to be cooled.

4. Electronic equipment mounted on a vehicle comprising the heat radiating device according to claim 1.
